(19) United States
(12) Patent Application Publication
(10) Pub. No.: US 2010/0142035 A1
(43) Pub. Date: Jun. 10, 2010

(54) FRONT FILTER FOR DISPLAY DEVICE AND METHOD OF MANUFACTURING THE SAME

(76) Inventor: Jae-Young Yeo, Suwon-si (KR)

Correspondence Address: CHRISTIE, PARKER & HALE, LLP, PO BOX 7068, PASADENA, CA, 91109-7068, US

(21) Appl. No.: 12/629,563

(22) Filed: Dec. 2, 2009

(30) Foreign Application Priority Data
Dec. 5, 2008 (KR) 10-2008-0123145

(51) Int. Cl. G02B 5/20; H05K 9/00; G02B 27/00; B05D 5/12; C23C 14/34

(52) U.S. Cl. 359/361; 174/350; 359/609; 427/64; 204/192.1

(57) ABSTRACT

A front filter for improving quality of a display device by improving a shielding capability of the filter and a method of manufacturing the front filter. In one embodiment, the front filter includes a base substrate, a first shielding structure, and a second shielding structure. The first shielding structure includes a first lower insulating layer on the base substrate, a first conductive layer on the first lower insulating layer, and a first upper insulating layer on the first conductive layer. The second shielding structure includes a second lower insulating layer on the first upper insulating layer, a second conductive layer on the second lower insulating layer, and a second upper insulating layer on the second conductive layer. In the front filter, an edge of the first shielding structure is exposed to an outside of the second shielding structure.

### CROSS-REFERENCE TO RELATED APPLICATION

This application claims priority to and the benefit of Korean Patent Application No. 10-2008-0123145, filed on Dec. 5, 2008, in the Korean Intellectual Property Office, the entire content of which is incorporated herein by reference.

### BACKGROUND OF THE INVENTION

1. Field of the Invention

An aspect of the present invention relates to a front filter for improving quality of a display device by enhancing a shielding capability of the filter and a method of manufacturing the front filter.

2. Description of Related Art

A plasma display device including a plasma display panel (PDP) is a flat panel display device which displays images utilizing a gas discharge phenomenon.

Since high voltage and high frequency are used in a driving process of the aforementioned plasma display device, a large quantity of electromagnetic waves are radiated to the front of the PDP. Further, the plasma display device emits near infrared (NIR) radiation induced by an inert gas such as Ne or Xe. Such NIR radiation has a wavelength very close to that of a typical remote control, thereby resulting in possible malfunctions of electric appliances. Furthermore, glass disposed in front of the PDP reflects external light, thereby resulting in glare, degradation of contrast or the like. Therefore, in most plasma display devices, a filter is provided in front of the PDP so as to compensate for these problems.

A front filter may be film-type filters utilizing a single material film have been used to decrease the price of plasma display devices.

However, for a film-type filter to obtain low surface resistance required in a plasma display device, a complicated and precise process for exposing the ground portion may have to be performed. Therefore, manufacturing cost is unavoidably increased, and the yield of products is decreased.

As described above, there are needs for applying film-type filters to plasma display devices instead of tempered glass filters because of their light, thin and low-priced characteristics. However, there is still a need to improve the structure of high cost consumed in processing a ground portion of an electromagnetic shielding layer.

### SUMMARY OF THE INVENTION

An aspect of an embodiment of the present invention is directed toward a method of manufacturing a front filter that can be easily manufactured and having an improved shielding capability (or improved shielding force).

An aspect of an embodiment of the present invention is directed toward a front filter for a display device manufactured utilizing the aforementioned method, so that surface resistance required in the display device is secured, thereby improving shielding capability and quality of the display device.

According to an embodiment of the present invention, there is provided a front filter for a display device, which includes a base substrate; a first shielding structure, and a second shielding structure. The first shielding structure includes a first lower insulating layer on the base substrate, a first conductive layer on the first lower insulating layer, and a first upper insulating layer on the first conductive layer. The second shielding structure includes a second lower insulating layer on the first upper insulating layer, a second conductive layer on the second lower insulating layer, and a second upper insulating layer on the second conductive layer. Here, an edge of the first shielding structure is exposed to an outside of the second shielding structure.

According to another embodiment of the present invention, there is provided a front filter for a display device, which includes a base substrate, a first shielding structure, and a second shielding structure. The first shielding structure includes a first conductive layer on the base substrate, and a first insulating layer on the first conductive layer. The second shielding structure includes a second conductive layer on the first insulating layer, and a second insulating layer on the second conductive layer. Here, an edge of the first shielding layer is exposed to an outside of the second shielding layer.

The first insulating layer may cover a ground portion of the first conductive layer positioned at the edge of the first shielding structure.

According to still another embodiment of the present invention, there is provided a method of manufacturing a front filter for a display device, which includes sequentially depositing a first lower insulating layer, a first conductive layer and a first upper insulating layer on a base substrate to form a first shielding structure; covering an edge of the first shielding structure with a first adhesive member; sequentially depositing a second lower insulating layer, a second conductive layer and a second upper insulating layer on the first shielding structure to form a second shielding structure; and removing the first adhesive member from the edge of the first shielding structure.

The method may further include covering an edge of the second shielding structure with a second adhesive member; sequentially depositing a third lower insulating layer, a third conductive layer and a third upper insulating layer on the second shielding structure to form a third shielding structure; and removing the second adhesive member from the edge of the second shielding structure.

The process of forming the first and second conductive layers may include a sputtering process.

As such, in embodiments of the present invention, a front filter for a display device can be easily manufactured through improvement and/or modification of a conventional structure without increasing (or substantially increasing) manufacturing cost.

Further, in a shielding structure of an embodiment of the present invention including a conductive layer with a multiple-layered structure, surface resistance of a ground portion electrically connected to a ground terminal of a panel is lowered, thereby improving a shielding force of a filter and enhancing quality of a display device.

### BRIEF DESCRIPTION OF THE DRAWINGS

The accompanying drawings, together with the specification, illustrate exemplary embodiments of the present invention, and, together with the description, serve to explain the principles of the present invention.

FIG. 1 is a schematic view illustrating a plasma display device utilizing a front filter according to an embodiment of the present invention.

FIGS. 2A and 2B are partial cross-sectional views of a front filter according to an embodiment of the present invention.

FIG. 3A is a graph showing an electric field strength of noise voltage with respect to a frequency in a front filter according to a comparative example.

FIG. 3B is a graph showing an electric field strength of noise voltage with respect to a frequency in a front filter according to an embodiment of the present invention.

FIG. 4 is a cross-sectional view of a front filter according to another embodiment of the present invention.

### DETAILED DESCRIPTION

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. In addition, when an element is referred to as being “on” another element, it can be directly on the another element or be indirectly on the another element with one or more intervening elements interposed therebetween. Also, when an element is referred to as being “connected to” another element, it can be directly connected to the another element or be indirectly connected to the another element with one or more intervening elements interposed therebetween. Hereinafter, like reference numerals refer to like elements.

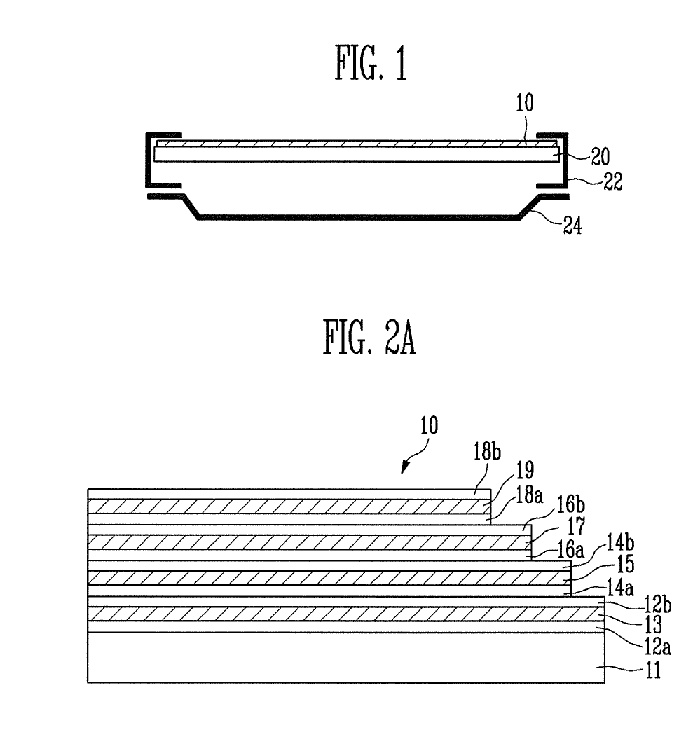

FIG. 1 is a schematic view illustrating a plasma display device utilizing a front filter according to an embodiment of the present invention.

Referring to FIG. 1, the plasma display device includes a front filter 10, a plasma display panel (PDP) 20, a filter holder 22 and a back cover 24. The front filter 10 is disposed in front of the PDP 20 and supported by the filter holder 22. The plasma display device may include a chassis base connected at the back of the PDP 20, and a driving circuit board on which one or more electric circuits for driving the PDP 20 are mounted.

For example, the PDP 20 may include a front plate having X-Y electrodes, a dielectric layer and a protection layer, disposed on one surface of a first substrate; and a back plate having address electrodes, a dielectric layer, barrier ribs and a phosphor layer, disposed on a second substrate facing (or opposite to) the first substrate.

In one embodiment, the front filter 10 is a film-type filter disposed on a visible surface of the PDP 20. In one embodiment, the front filter 10 is a film-type filter utilizing a single material film.

Generally, a front filter in a plasma display device may have an electromagnetic shielding structure utilizing a conductive mesh or conductive layer. Accordingly, the front filter 10 according to the embodiment of the present invention has an electromagnetic shielding structure utilizing a conductive layer, in which its manufacturing process is easily performed, thereby saving manufacturing cost. The electromagnetic shielding structure utilizing a conductive layer may be easily formed utilizing a sputtering process.

In one embodiment, the electromagnetic shielding structure utilizing a conductive layer is transparent to light (i.e., has the necessarily light transmittance) and shielding capability required in the display device. However, if the thickness of the conductive layer is increased, the shielding capability of the filter is increased, but the light transmittance of the filter is decreased. If the thickness of the conductive layer is decreased, the light transmittance of the filter is increased, but the shielding force of the filter is decreased. Here, the electromagnetic shielding structure according to one embodiment of the present invention has a structure in which conductive layers and transparent insulating layers are alternately laminated.

However, in the electromagnetic shielding structure formed by alternately laminating the insulating layers and the conductive layers, the contact resistance of a ground portion electrically connected to a ground terminal of the PDP 20 is increased due to the insulating layers covering ground portions of the respective conductive layers. Therefore, a shielding capability required in the electromagnetic shielding structure cannot be obtained. Since the conductive layers are laminated in the electromagnetic shielding structure, the uppermost conductive layer can be electrically connected to a gasket with relative ease. However, it is relatively difficult to electrically connect the gasket to the other conductive layers positioned beneath the uppermost conductive layer.

Although a method of selectively removing the insulating layers covering the ground portions of the respective conductive layers may be considered, this method increases manufacturing costs, and ground portions of the conductive layers exposed to the outside are easily oxidized. Accordingly, in one embodiment, a front filter 10 is provided that is capable of improving a shielding capability of a filter not by removing the insulating layers covering the ground portions of the respective conductive layers but by effectively decreasing the contact resistance of the ground portion connected to the ground terminal of the PDP 20.

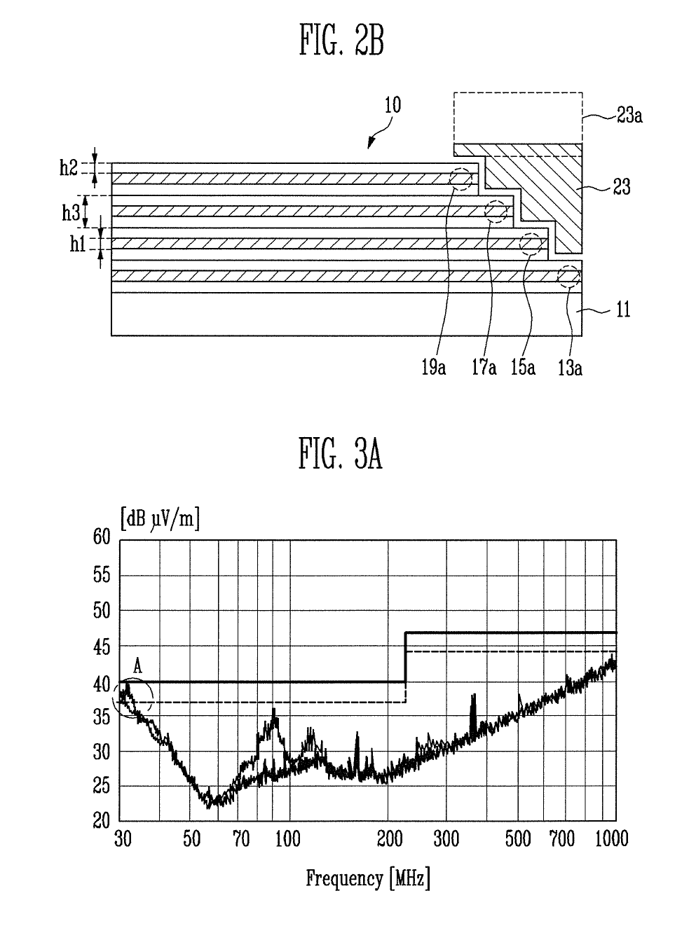

FIGS. 2A and 2B are partial cross-sectional views of a front filter according to an embodiment of the present invention.

Referring to FIG. 2A, the front filter 10 includes a first lower insulating layer 12a, a first conductive layer 13, a first upper insulating layer 12b, a second lower insulating layer 14a, a second conductive layer 15, a second upper insulating layer 14b, a third lower insulating layer 16a, a third conductive layer 17, a third upper insulating layer 16b, a fourth lower insulating layer 18a, a fourth conductive layer 19 and a fourth upper insulating layer 18b, which are sequentially laminated on a base substrate 11.

The base substrate 11 is a material selected based on a desired dynamic and/or optical property. In one embodiment, the base substrate 11 has a high mechanical strength, a low thermal shrinkage rate, and a small amount of oligomer produced by heating.

In this embodiment, the front filter 10 includes four conductive layers 13, 15, 17 and 19 laminated to obtain surface resistance and transmittance required in a display device. The respective conductive layers constitute transparent shielding structures together with insulating layers disposed therebetween. In other words, a first shielding structure includes the first lower insulating layer 12a, the first conductive layer 13 and the first upper insulating layer 12b. A second shielding structure includes the second lower insulating layer 14a, the second conductive layer 15 and the second upper insulating layer 14b. A third shielding structure includes the third lower insulating layer 16a, the third conductive layer 17 and the third upper insulating layer 16b. And, a fourth shielding structure includes the fourth lower insulating layer 18a, the fourth conductive layer 19 and the fourth upper insulating layer 18b. Here, an edge of the first shielding structure is exposed to the outside of the second shielding structure, and an edge of the second shielding structure is exposed to the outside of the third shielding structure. An edge of the third shielding structure is exposed to the outside of the fourth shielding structure.

According to the aforementioned structure, the front filter 10 includes first to fourth shielding structures having edges arranged into a continuous stepped structure.

Accordingly, a ground portion 13a, 15a, 17a, 19a of each of the conductive layers 13, 15, 17 and 19 can be connected to a ground terminal of a panel through one upper insulating layer, e.g., by a tunneling effect. The ground portions of the conductive layers 13, 15, 17 and 19 positioned at their edges are covered by the upper insulating layers 12b, 14b, 16b and 18b, respectively. Accordingly, the ground portion 13a, 15a, 17a, 19a of each of the conductive layers 13, 15, 17, and 19 is not exposed to the outside, and therefore, each of the conductive layers is protected from oxidation.

Each of the conductive layers 13, 15, 17 and 19 is formed of a material having relatively high conductivity. For example, silver (Ag), indium tin oxide (ITO) or the like is suitable for the material of each of the conductive layers. In addition, a metal layer, a metal oxide, a conductive polymer or the like may be used as the material of each of the conductive layers. The metal layer includes palladium, copper, platinum, rhodium, aluminum, ferrum, cobalt, nickel, zinc, ruthenium, stannum, tungsten, iridium, plumbum and/or argentum. The metal oxide includes stannic oxide, indium oxide, antimony oxide, zinc oxide, zirconium oxide, titanium oxide, magnesium oxide, silicon oxide, aluminum oxide, metal alkoxide, indium tin oxide (ITO) and/or antimony tin oxide (ATO).

As shown in FIG. 2B, the thickness h1 of each of the conductive layers is set to be in a range to have suitable conductivity and transmittance (that is enough conductivity without overly decreasing the transmittance). For example, when the conductive layers are made of silver (Ag), the thickness h1 of each of the conductive layers is formed to be between about 10 and 16 nm. In one embodiment, if the thickness of each of the conductive layers made of silver (Ag) is below 10 nm, the conductivity is too low. In another embodiment, if the thickness of each of the conductive layers made of silver (Ag) is over 16 nm, the transmittance is too low.

Each of the insulating layers 12a, 12b, 14a, 14b, 16a, 16b, 18a and 18b is made of an oxide and/or nitride. As shown in FIG. 2B, the thickness h2 of each of the insulating layers is formed to be about 50 nm. The thickness h3 of each of the shielding structures is a value (e.g., a minimum value) selected to result in a desired low resistance without overly decreasing its transmittance. In one embodiment, if the thickness h3 of each of the shielding structures is thicker than 50 nm, material and manufacturing costs are increased.

The process of allowing the ground portions of the front filter 10 to be electrically connected to the ground terminal of the panel will be described as follows.

As shown in FIG. 2B, each of the ground portions 13a, 15a, 17a and 19a of the front filter 10 is connected to the ground terminal of the panel through a gasket 23 and a wire electrically connected to the gasket 23. The gasket 23 includes a conductive elastic body interposed between a filter holder and the front filter 10 when the filter holder presses and supports an edge of the front filter 10 opposite to the front of the panel. For example, the gasket 23 includes a conductive sponge on which a conductive material such as aluminum is coated. Portion 23a indicated by a dotted line shows a position of the gasket 23 before it is pressed by the filter holder.

Alternatively, the gasket 23 may be implemented as a stepped gasket formed so that portions being in contact with the ground portions 13a, 15a, 17a and 19a are formed to have a stepped shape like the external shape shown in FIG. 2B. In this case, the gasket 23 may include not only a sponge but also a conductive material harder than the sponge.

According to the aforementioned configuration, the ground portions 13a, 15a, 17a and 19a respectively covered by the insulating layers are electrically connected one by one to the gasket 23 due to the tunneling effect, and a side of each of the ground portions is in contact with the gasket 23. Accordingly, contact resistance of the ground portions of the front filter 10 is lowered.

Hereinafter, a method of manufacturing the front filter 10 will be briefly described with reference to FIG. 2A.

First, a first low insulating layer 12a, a first conductive layer 13 and a first upper insulating layer 12b are sequentially formed on a base substrate 11. At this time, the first conductive layer 13 is deposited to a thickness of 16 nm or less utilizing a sputtering process. A large-area thin film can be easily formed utilizing the sputtering process.

Subsequently, a first adhesive member is attached on an edge of the first upper insulating layer 12b. The first adhesive member includes an attachable/detachable tape.

Then, a second lower insulating layer 14a, a second conductive layer 15 and a second upper insulating layer 14b are sequentially formed on the first upper insulating layer 12b. Like the first conductive layer 13, the second conductive layer 15 is also deposited to a thickness of 16 nm or less utilizing a sputtering process.

Next, a second adhesive member is attached on an edge of the second upper insulating layer 14b. The second adhesive member includes a tape having a wider width than that of the first adhesive member.

Subsequently, a third lower insulating layer 16a, a third conductive layer 17 and a third upper insulating layer 16b are sequentially formed on the second upper insulating layer 14b. Like the first and second conductive layers 13 and 15, the third conductive layer 17 is also deposited to a thickness of 16 nm or less utilizing a sputtering process.

Then, a third adhesive member is attached on an edge of the third upper insulating layer 16b. The third adhesive member includes a tape having a wider width than that of the second adhesive member.

Subsequently, a fourth lower insulating layer 18a, a fourth conductive layer 19 and a fourth upper insulating layer 18b are sequentially formed on the third upper insulating layer 16b. Like the first to third conductive layers 13, 15 and 17, the fourth conductive layer 19 is also deposited to a thickness of 16 nm or less utilizing a sputtering process.

Next, the third, second and first adhesive members are detached from the upper insulating layers 16b, 14b and 12b, respectively.

According to the aforementioned configuration, the front filter 10 can be easily manufactured, which has the ground portions individually connected to the gasket while being protected by the respective insulating layers.

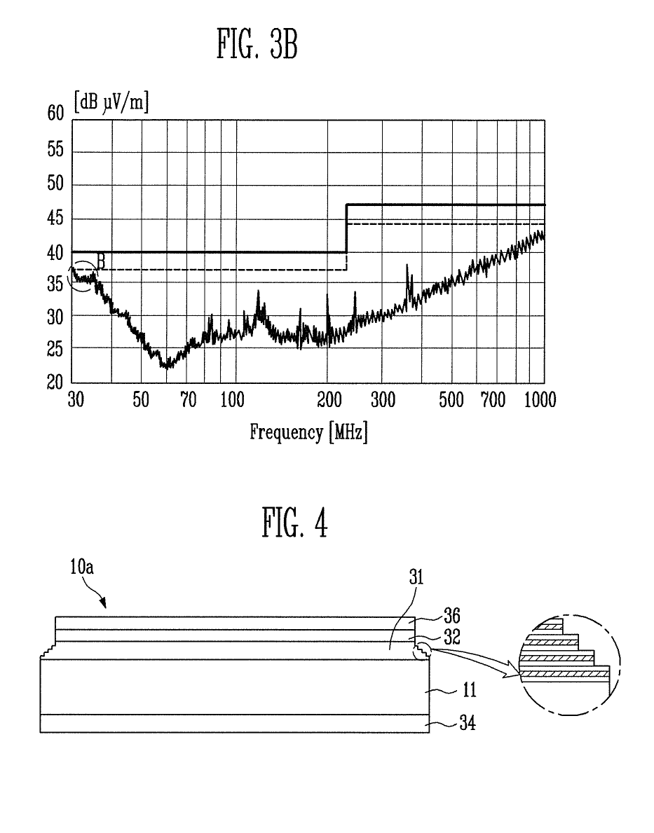

FIG. 3A is a graph showing an electric field strength of noise voltage with respect to a frequency in a front filter according to a comparative example. FIG. 3B is a graph showing an electric field strength of noise voltage with respect to a frequency in a front filter according to an embodiment of the present invention.

The front filter according to the comparative example was manufactured so that shielding structures each having a lower insulating layer, a conductive layer and an upper insulating layer are stacked to have a height up to the four shielding structures, and the shielding structures do not have a stepped shape. The front filter according to the embodiment of the present invention was manufactured so that shielding structures each having a lower insulating layer, a conductive layer and an upper insulating layer are stacked to have a height up to the four shielding structures, and the shielding structures have a stepped shape.

Referring to FIG. 3A, a plasma display device employing the front filter according to the comparative example produced a noise of about 40 dB μV/m in the vicinity of 30 MHz. This is because contact resistance is increased with respect to how far a gasket on the uppermost conductive layer is away from the other conductive layers.

Referring to FIG. 3B, a plasma display device employing the front filter according to the embodiment of the present invention produced a noise of about 38 dB μV/m in the vicinity of 30 MHz. This is because contact resistance does not increase as the respective conductive layers (stacked to have a height up to the four shielding structures) are individually connected to a gasket.

As described above, a shielding capability of a filter can be improved utilizing a front filter according to an embodiment of the present invention.

FIG. 4 is a cross-sectional view of a front filter according to another embodiment of the present invention.

Referring to FIG. 4, the front filter 10a includes an electromagnetic shielding layer 31, a color coating layer 32 and an anti-reflection layer 36, sequentially laminated on one surface of a base substrate 11, and an adhesive layer 34 formed on the other surface of the base substrate 11. Here, the base substrate 11 and the electromagnetic shielding layer 31 correspond to the front filter 10 of the aforementioned embodiment.

In the front filter 10a, a ground portion with a stepped structure, positioned at an edge portion of the electromagnetic shielding layer 31, may be formed at two sides opposite to each other, at three sides or all sides (e.g., at all four sides).

The base substrate 11 serves as a base member of the front filter 10a and is made of a material having a transmittance between 80 and 99%; and having low reflectance, lower thermal resistance and suitable strength. Particularly, polyethylene terephthalate (PET) is suitable as a material of the base substrate 11. In addition, the material of the base substrate 11 may include polyethersulphone (PES), polyacrylate (PAR), polyetherimide (PEI), polyethylene napthalate (PEN), polyphenylene sulfide (PPS), polyallylate, polyimide, polycarbonate, triacetate cellulose (TAC), cellulose acetate propionate (CAP) and the like.

The color coating layer 32 includes a coloring matter for color correction, near infrared shielding or orange wavelength absorption. The coloring matter includes a dye or pigment. For example, the coloring matter includes a nickel complex-based, phthalocyanine-based, naphthalocyanine-based, cyanine-based, diimmonium-based, squarylium-based, axomethine-based, xanthene-based, oxonol-based or azo-based material, which can shield a wavelength between about 800 and about 1200 nm or shields or absorbs a wavelength between about 585 and about 620 nm. The kind and concentration of the coloring matter may be determined based on the absorption wavelength and coefficient of a coloring matter, the color tone of a transparent conductive layer, the transmittance characteristic and transmittance required in the filter, and the like.

The adhesive layer 34 is used to attach the front filter 10a on a visible surface of a display device such as a PDP. A material of the adhesive layer 34 may include an acryl-based, silicon-based, urethane-based or polyvinyl-based thermoplastic resin and/or a transparent adhesive or gluing agent such as a UV curing resin. For example, a silicon adhesive such as an acrylate-based resin or pressure sensitive adhesive (PSA) may be used as the material of the adhesive layer 34.

Also, the adhesive layer 34 may include a coloring matter for color correction, near infrared shielding or orange wavelength absorption. In this case, the color coating layer 36 may be omitted, and the anti-reflection layer 36 may be directly formed on the electromagnetic shielding layer 31.

The anti-reflection layer 36 formed is used to reduce (or minimize) loss of light passing therethrough and to prevent the reflection and diffused reflection of external light. The anti-reflection layer 36 may be formed into a single- or multiple-layered structure. The single-layered anti-reflection layer 36 is formed to a thickness having ¼ of the wavelength of an optical film utilizing a fluorine-based transparent polymer resin, a fluorinated magnesium based resin, silicon-based resin, and/or a silicon oxide thin film. The multiple-layered anti-reflection layer 36 is formed by stacking organic and inorganic compound thin films up to two stories or higher. Here, the organic compound thin film is made of a metallic oxide, a fluoride, a silicide, a boride, a carbide, a nitride, a sulfide or the like, and the inorganic compound thin film is made of a silicon-based resin, an acrylic resin or a fluorine-based resin. The organic and inorganic compound thin films have different refractive indices. The anti-reflection layer 36 may be formed utilizing a method such as sputtering, ion plating, ion beam assisting, vacuum deposition, chemical vapor deposition (CVD) or physical vapor deposition (PVD).

The anti-reflection layer 36 may include a film performing an anti-reflection function and a hard coating member formed on one surface (top surface) of the film. Here, the hard coating member is used to reduce or prevent scratches caused by various types of external forces. An acryl-based, urethane-based, epoxy-based or siloxane-based polymer may be used as a material of the hard coating member. Alternatively, a UV curing resin such as oligomer may be used as the material of the hard coating member. A silica-based filler may be added to improve the strength of the hard coating member. The thickness of the anti-reflection layer 36 including the hard coating member is formed to a thickness between 2 and 7 μm so as to obtain an expected effect while not being too thick.

In another embodiment, the hard coating member may not be inserted into the film performing the anti-reflection function but may be formed on the other surface (bottom surface) of the film.

The front filter 10a including the hard coating member has optical characteristics having a low haze of between 1 and 3%, a visible light transmittance of between 30 and 90%, a low external light reflectance of between 1 and 20%, a thermal resistance of a glass transition temperature or more, and a pencil hardness of between 1 and 3H.

Also, it has been described in the aforementioned embodiments that an electromagnetic shielding structure has upper and lower insulating layers with a conductive layer therebetween, and a plurality of such electromagnetic shielding structures are stacked. This is because the thickness of an insulating layer covering a ground portion positioned at an edge of a conductive layer can be made to be relatively thin, thereby lowering contact resistance between the ground portion and a gasket. However, the present invention is not limited thereto. For example, in one embodiment, an insulating material having an improved insulation property may be used, so that a conductive layer of a second shielding structure is formed on an upper insulating layer of a first shielding structure without a lower insulating layer of the second shielding structure.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A front filter for a display device, comprising:
a base substrate;
a first shielding structure comprising:
a first lower insulating layer on the base substrate,
a first conductive layer on the first lower insulating layer, and
a first upper insulating layer on the first conductive layer; and
a second shielding structure comprising:
a second lower insulating layer on the first upper insulating layer,
a second conductive layer on the second lower insulating layer, and
a second upper insulating layer on the second conductive layer,
wherein an edge of the first shielding structure is exposed to an outside of the second shielding structure.

2. The front filter of claim 1, further comprising:
a third shielding structure on the second shielding structure; and
a fourth shielding structure on the third shielding structure,
wherein an edge of the fourth shielding structure is exposed to an outside of the third shielding structure, and an edge of the third shielding structure is exposed to an outside of the second shielding structure.

3. The front filter of claim 2, wherein the first, second, third, and fourth upper insulating layers are respectively on ground portions of the first, second, third, and fourth conductive layers respectively at the edges of the first, second, third, and fourth shielding structures.

4. The front filter of claim 2, wherein the first, second, third, and fourth shielding structures have a stepped shape.

5. The front filter of claim 4, wherein the first, second, third, and fourth shielding structures are grounded through a conductive sponge or stepped sponge.

6. The front filter of claim 2, further comprising a color coating layer on an upper insulating layer of the fourth shielding structure.

7. The front filter of claim 6, wherein the color coating layer comprises a coloring matter for color correction, near infrared shielding or orange wavelength absorption.

8. The front filter of claim 2, further comprising an anti-reflection layer on the fourth shielding structure.

9. The front filter of claim 1, further comprising an adhesive layer beneath the base substrate.

10. The front filter of claim 1, wherein the conductive layers comprise silver (Ag).

11. The front filter of claim 10, wherein each of the conductive layers has a thickness of about 16 nm or less.

12. The front filter of claim 1, wherein the insulating layers include an oxide or nitride.

13. The front filter of claim 12, wherein each of the shielding structures has a thickness of about 50 nm.

14. A front filter for a display device, comprising:
a base substrate;
a first shielding structure comprising:
a first conductive layer on the base substrate, and
a first insulating layer on the first conductive layer;
a second shielding structure comprising: a second conductive layer on the first insulating layer, and
a second insulating layer on the second conductive layer,
wherein an edge of the first shielding layer is exposed to an outside of the second shielding layer.

15. The front filter of claim 14, wherein the first insulating layer covers a ground portion of the first conductive layer positioned at the edge of the first shielding structure.

16. A method of manufacturing a front filter for a display device, the method comprising:
sequentially depositing a first lower insulating layer, a first conductive layer and a first upper insulating layer on a base substrate to form a first shielding structure;
covering an edge of the first shielding structure with a first adhesive member;
sequentially depositing a second lower insulating layer, a second conductive layer and a second upper insulating layer on the first shielding structure to form a second shielding structure; and
removing the first adhesive member from the edge of the first shielding structure.

17. The method of claim 16, further comprising:
covering an edge of the second shielding structure with a second adhesive member;
sequentially depositing a third lower insulating layer, a third conductive layer and a third upper insulating layer on the second shielding structure to form a third shielding structure; and
removing the second adhesive member from the edge of the second shielding structure.

18. The method of claim 16, wherein the process of forming the first and second conductive layers includes a sputtering process.
